(19) United States
(12) Patent Application Publication
(10) Pub. No.: US 2014/0216547 A1
(43) Pub. Date: Aug. 7, 2014

(54) OVERSIZED BACK PANEL FOR PHOTOVOLTAIC DEVICES

(71) Applicant: PRIMESTAR SOLAR, INC., Arvada, CO (US)

(72) Inventors: Troy Alan Berens, Evergreen, CO (US); Max William Reed, Niwot, CO (US); Jeffrey Scott Erlbaum, Albany, NY (US); David W. Vernooy, Niskayuna, NY (US); Venkata Sai Rahul Chandra Abbaraju, Denver, CO (US); Boaz Alperson, Rensselaer, NY (US)

(73) Assignee: PRIMESTAR SOLAR, INC., Arvada, CO (US)

(21) Appl. No.: 13/758,185

(22) Filed: Feb. 4, 2013

(51) Int. Cl. H01L 31/048

(52) U.S. Cl. CPC H01L 31/0488
USPC 136/259

(57) ABSTRACT

Thin film photovoltaic devices including a transparent substrate defining a front surface area; a photovoltaic thin film stack on the transparent substrate; and, a back panel defining a rear surface area are provided. The photovoltaic thin film stack is positioned between the transparent substrate and the back panel. The front surface area can be less than the rear surface area (e.g., about 90% to about 99.9% of the rear surface area). As such, the back panel can extend farther than the transparent substrate along at least one edge of the device. An encapsulant layer defining an encapsulant surface area can be positioned between the photovoltaic thin film stack and the back panel. The encapsulant surface area can be greater than or equal to the front surface area or can be less than or equal to the rear surface area.

### FIELD OF THE INVENTION

The subject matter disclosed herein relates generally to an oversized back panel for use in a photovoltaic device, along with their methods of deposition. More particularly, the subject matter disclosed herein relates to an oversized back panel for use in photovoltaic devices having a front substrate made from a specialty glass and their methods of manufacture.

### BACKGROUND OF THE INVENTION

Thin film solar modules are typically constructed with a front material (usually glass) and a back material (also usually glass) that are sealed together to protect the internal device while it is in service. The front material is ideally transparent to light (i.e., radiation energy) at the wavelengths corresponding to the energy conversion with minimal absorption and/or reflection in order to allow the maximum amount of available light to reach the underlying thin films. Many factors can affect the amount of absorption and/or reflection of the front material, such as the thickness of the front material, the type of material selected, etc. For example, reducing the thickness of the front material may lead to less absorption in the front material.

One material that is currently used in many thin film solar modules as both the front material and the back material is soda-lime glass. Other specialty glasses, such as borosilicate glasses, can also be used. However, such specialty glasses tend to be more expensive than soda-lime glasses, prompting a push toward thinner glass use, to lessen material costs. Yet, reducing the thickness of such a front material can lead to unwanted side-effects, such as a loss in overall strength of the front material and an increased tendency toward overall module failure.

For example, one of the main drawbacks of glass as a front surface is that, in order to maintain high strength, the panel must be thick enough and hence heavy. In fact, the glass is often the heaviest component of a solar module. The added weight increases the cost of transportation, difficulties in installation, and the racking needed to bear the weight of the modules over several decades of service. However, decreasing the thickness of the cover glass means less protection from impact of objects including hail, falling branches, or tools used during installation and maintenance.

The side edges of the glass often serve as a source of weakness within a given module. Some modules, accordingly, are designed with a frame protecting the edges. Such frames also add weight and cost and can increase the installation burden, in the case of a metal frame which must be electrically grounded. However, the thinner front panel and the elimination of frames can make the edges of the modules more susceptible to impact damage.

As such, a need exists to protect the edges of a solar module without the use of a frame, particularly when using a relatively thin transparent substrate as the front of the module.

### BRIEF DESCRIPTION OF THE INVENTION

Aspects and advantages of the invention will be set forth in part in the following description, or may be obvious from the description, or may be learned through practice of the invention.

Thin film photovoltaic devices are generally provided that include a transparent substrate defining a front surface area; a photovoltaic thin film stack (e.g., a transparent conductive oxide layer, a photovoltaic heterojunction, and back contact layer) on the transparent substrate; and, a back panel defining a rear surface area. The photovoltaic thin film stack is positioned between the transparent substrate and the back panel.

In one embodiment, the front surface area is less than the rear surface area. For example, the front surface area can be about 90% to about 99.9% of the rear surface area, such as about 95% to about 99.5% of the rear surface area.

The back panel can, in certain embodiments, extend farther than the transparent substrate along at least one edge of the device, along at least two edges of the device, along at least three edges of the device, etc. In one particular embodiment, the device defines a rectangle having four edges with the back panel extending farther than the transparent substrate along each edge of the device.

An encapsulant layer defining an encapsulant surface area can be positioned between the photovoltaic thin film stack and the back panel. The encapsulant surface area can, in one embodiment, be greater than or equal to the front surface area. Similarly, the encapsulant surface area can, in one embodiment, be less than or equal to the rear surface area. For example, the front surface area of the transparent substrate can be about 95% to 100% of the encapsulant surface area, such as about 95% to 99% of the rear surface area.

In one particular embodiment, the back panel extends farther than the transparent substrate along at least one portion of the device (e.g., along at least one edge of the device).

Methods are also generally provided for forming such photovoltaic devices.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 shows a general schematic of a top view of an exemplary thin film photovoltaic device of one embodiment of the present invention;

FIG. 2 shows a cross-sectional side view of the exemplary thin film photovoltaic device of FIG. 1;

FIG. 3 shows another cross-sectional side view of the exemplary thin film photovoltaic device of FIG. 1;

FIG. 4 shows a general schematic of a top view of an exemplary thin film photovoltaic device of another embodiment of the present invention;

FIG. 5 shows a cross-sectional side view of the exemplary thin film photovoltaic device of FIG. 4;

FIG. 6 shows another cross-sectional side view of the exemplary thin film photovoltaic device of FIG. 4;

FIG. 7 shows a general schematic of a top view of an exemplary thin film photovoltaic device of yet another embodiment of the present invention;

FIG. 8 shows a cross-sectional side view of the exemplary thin film photovoltaic device of FIG. 7;

FIG. 9 shows another cross-sectional side view of the exemplary thin film photovoltaic device of FIG. 7; and,

FIG. 10 shows a general schematic of a cross-sectional view of an exemplary thin film stack for use in any of the devices shown in FIGS. 1-9.

Repeat use of reference characters in the present specification and drawings is intended to represent the same or analogous features or elements.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

In the present disclosure, when a layer is being described as “on” or “over” another layer or substrate, it is to be understood that the layers can either be directly contacting each other or have another layer or feature between the layers, unless expressly stated to the contrary. Thus, these terms are simply describing the relative position of the layers to each other and do not necessarily mean “on top of” since the relative position above or below depends upon the orientation of the device to the viewer. Additionally, although the invention is not limited to any particular film thickness, the term “thin” describing any film layers of the photovoltaic device generally refers to the film layer having a thickness less than about 10 micrometers (“microns” or “μm”).

It is to be understood that the ranges and limits mentioned herein include all ranges located within the prescribed limits (i.e., subranges). For instance, a range from about 100 to about 200 also includes ranges from 110 to 150, 170 to 190, 153 to 162, and 145.3 to 149.6. Further, a limit of up to about 7 also includes a limit of up to about 5, up to 3, and up to about 4.5, as well as ranges within the limit, such as from about 1 to about 5, and from about 3.2 to about 6.5.

Thin film photovoltaic devices are generally disclosed having a photovoltaic thin film stack between a transparent substrate (serving as the front material) and a back panel (serving as the back material). Generally, as will be discussed in greater detail below, the front surface area defined by the transparent substrate is less than the rear surface area defined by the back panel. For instance, the front surface area can be about 90% to about 99.9% of the rear surface area, such as about 95% to about 99.5% of the rear surface area. Thus, the transparent substrate has a smaller size relative to the back panel.

For example, in embodiments where the thin film photovoltaic device defines a rectangle (i.e., both of the transparent substrate and the back panel are rectangular), at least one of the length and/or width of the transparent substrate is less than that of the back panel. Such a configuration can allow for the back panel to extend farther than the transparent substrate along at least one edge of the device (e.g., along at least two edges).

The back panel is designed to have greater strength against forces and impact events relative to the front glass, which can be achieved by the choice of materials, by the thickness of the back panel, and/or by the use of a structural matrix. Thus, the back panel serves as a structural support for the transparent substrate, especially along the edges of the device.

Such a configuration ensures that the more fragile transparent substrate is never the recipient of contact or impact along an edge where the back panel does not extend farther on the device. Thus, the transparent substrate can only be contacted by objects travelling roughly perpendicular to the plane of the device. As long as the transparent substrate is supported by the encapsulant layer and the back panel, the transparent substrate can distribute the force of an impact to other components of the solar device and is furthermore stiffened by the intimate contact with the encapsulant layer.

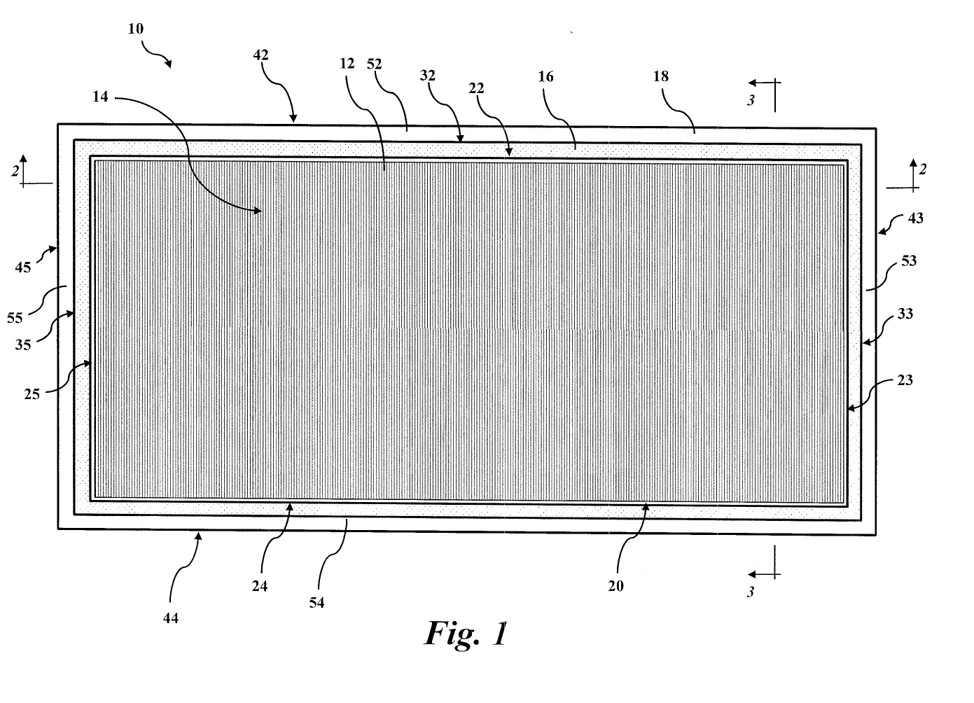

FIGS. 1-3 show an exemplary thin-film photovoltaic device 10. Each device 10 is shown including a transparent substrate 12 (e.g., a glass substrate), a photovoltaic thin film stack 14, an encapsulant layer 16, and a back panel 18. Generally, the photovoltaic thin film stack 14 is surrounded by an edge delete zone 20 that forms a border around the edges 22, 23, 24, 25 of the transparent substrate 12 where the photovoltaic thin film stack 14 is substantially omitted (e.g., has been substantially removed or was never present).

In the embodiment of FIG. 1, the device 10 includes a rectangular transparent substrate 12 and a rectangular back panel 18. The transparent substrate 12 defines four front edges 22, 23, 24, 25; and the back panel 18 defines four back edges 42, 43, 44, 45. Although shown having a length in the longitudinal direction that is greater than its width in the lateral direction, the device 10 can have any sized rectangle (including a square).

As stated, the back panel 18 extends farther than the transparent substrate 12 along each edge of the device 10 in the embodiment shown in FIG. 1 to define exterior edges of the device 10. In this embodiment, the transparent substrate 12 and back panel 18 are positioned with approximately common center points; however, the back panel 18 is longer in both its width and length than the transparent substrate 12. That is, the transparent substrate 12 defines a front length (extending between edge 23 and edge 25) and a front width (extending between edge 22 and edge 24) that are less than, respectively, a back length (extending between edge 43 and edge 45) and a back width (extending between edge 42 and edge 44) defined by the back panel 18. Thus, the front surface area defined by the transparent substrate 12 is less than the rear surface area defined by the back panel. In one particular embodiment, the transparent substrate 12 does not extend beyond any edge 42, 43, 44, 45 of the back panel 18.

In one embodiment, the transparent substrate 12 can be employed as a “superstrate,” as it is the substrate on which the subsequent layers are formed, even though it faces upward to the radiation source (e.g., the sun) when the photovoltaic device 10 is in use. The transparent substrate 12 can be a high-transmission glass (e.g., high transmission borosilicate glass), low-iron float glass, or other highly transparent glass material. The transparent substrate 12 is generally thick enough to provide support for the subsequent film layers, and is substantially flat enough, e.g., to provide a good surface for forming the subsequent film layers and to facilitate the appropriate laser scribing thereof. In one embodiment, the transparent substrate 12 can be a borosilicate glass with a thickness of about 0.5 mm to about 2.5 mm, such as about 0.7 mm to about 1.3 mm. Alternatively, the transparent substrate 12 can be a low-iron float glass with a thickness of about 1 mm to about 5 mm.

Due to the oversized back panel 18, the transparent substrate 12 can be thinner than the back panel 18. For example, the transparent substrate 12 can have a thickness that is about 10% to about 50% of the thickness of the back panel 18, while still remaining sufficiently strong in the resulting device 10.

The encapsulant layer 16 is positioned between the photovoltaic thin film stack 14 and the back panel 18 bonds the transparent substrate 12 and back panel 18 together and is the same size or larger than the transparent substrate 12. For example, the encapsulant surface area defined by the encapsulant layer can be equal to the front surface area defined by the transparent substrate 12 or greater, up to the rear surface area defined by the back panel 18. Similarly, the encapsulant surface area defined by the encapsulant layer can be equal to the rear surface area defined by the back panel 18 or less, down to the front surface area defined by the transparent substrate 12. That is, the side edges of the encapsulate layer 16 can be flush to the side edges of either the transparent substrate 12 or the back panel 18, or can be sized therebetween.

For example, the front surface area can be about 95% to 100% of the encapsulant surface area. Likewise, the encapsulant surface area can be about 95% to 99% of the rear surface area.

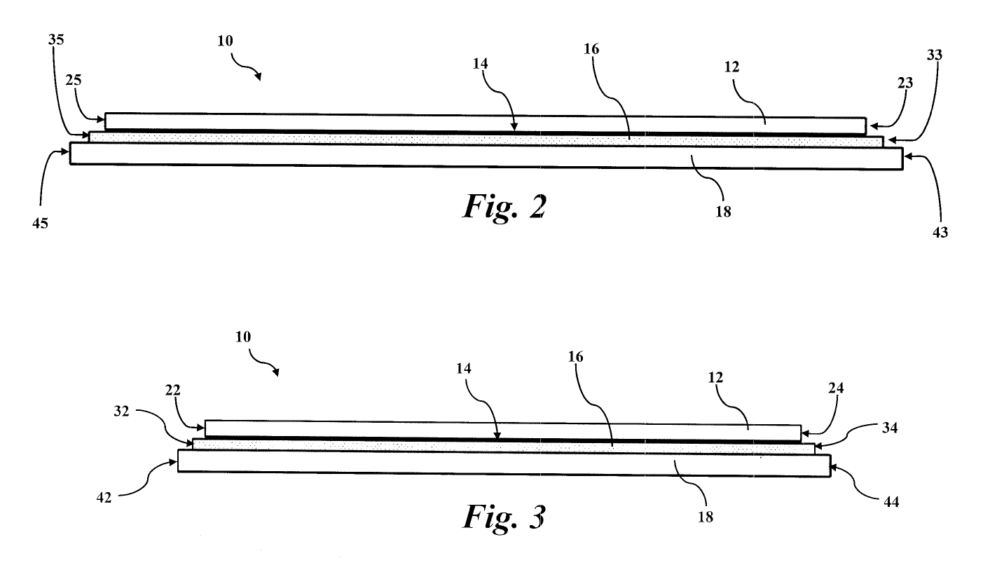

In the embodiment shown in FIG. 1, the encapsulant layer 16 is rectangularly shaped, defining edges 32, 33, 34, 35. The encapsulant length (extending between edge 33 and edge 35) is greater than the front length but less than the rear length, as more particularly shown in FIG. 2. Likewise, the encapsulant width (extending between edge 32 and edge 34) is greater than the front width but less than the rear width, as more particularly shown in FIG. 3. As such, edges 32, 33, 34, 35 extend farther than the respective edges 22, 23, 24, 25 of the transparent substrate 12 in the device 10. Such a configuration allows for an impact force along or near an edge 22, 23, 24, 25 of the transparent substrate 12 to be dissipated across the encapsulation layer 16 and the back panel 18. That is, as long as the transparent substrate 12 is supported by the encapsulant layer 16, the transparent substrate 12 can distribute the force of an impact to other components of the device 10 and is furthermore stiffened by the intimate contact with the encapsulant layer 16 and/or the back panel 18.

As shown in FIG. 1, a lip 52 is defined by the device 10 between the side edge 22 of the transparent substrate 12 and the side edge 42 of the back panel 18. Similarly, a lip 53 is defined by the device 10 between the side edge 23 of the transparent substrate 12 and the side edge 43 of the back panel 18. Likewise, a lip 54 is defined by the device 10 between the side edge 24 of the transparent substrate 12 and the side edge 44 of the back panel 18. Finally, a lip 55 is defined by the device 10 between the side edge 25 of the transparent substrate 12 and the side edge 45 of the back panel 18. Each of the lips 52, 53, 54, 55 can have the same size (defined by the shortest distance from the respective side edge 22, 23, 24, 25 of the transparent substrate 12 to the respective side edge 42, 43, 44, 45 of the back panel 18), or can have sizes that are different from each other. Similarly, the size of each lip 52, 53, 54, 55 can be constant across the edge of the device 10, or may be varied (e.g., a curved side edge of either or both of the transparent substrate 12 or the back panel 18).

In one embodiment, the encapsulant layer 16 can include a film forming binder that can aid in the adherence and bonding mechanism of the device 10. For example, the film forming binder can include, but is not limited to, ethylene vinyl acetate (EVA), epoxy resins, an ionomer, or copolymers thereof or mixtures thereof.

The process of forming the binder generally involves a lamination process, which may include placing the transparent substrate 12, the encapsulant layer 16 (including the binder), and back panel 18 at a high temperature (e.g., in the range of about 100° C. to about 170° C.) while the binder cures, crosslinks, etc. to form the permanent bond between the transparent substrate 12 and the back panel 18. This permanent bond can help seal the device 10 from the elements over its expected lifetime in the field. Thus, the encapsulant layer 16 can be included in the device 10 to aid in the lamination of the transparent substrate 12, the thin film stack 14, and the back panel 18 together. The encapsulation layer 16 can include, for example, ethylene vinyl acetate (EVA), epoxy resins, a thermal plastic, an acrylic adhesive, etc. or mixtures thereof.

As stated, the back panel 18 need only extend farther than the transparent substrate 12 along at least one edge of the device 10, if that edge is the exposed edge when deployed in the field. In other embodiments, the back panel 18 extends farther than the transparent substrate 12 along at least two edges of the device, such as along at least three edges of the device 10.

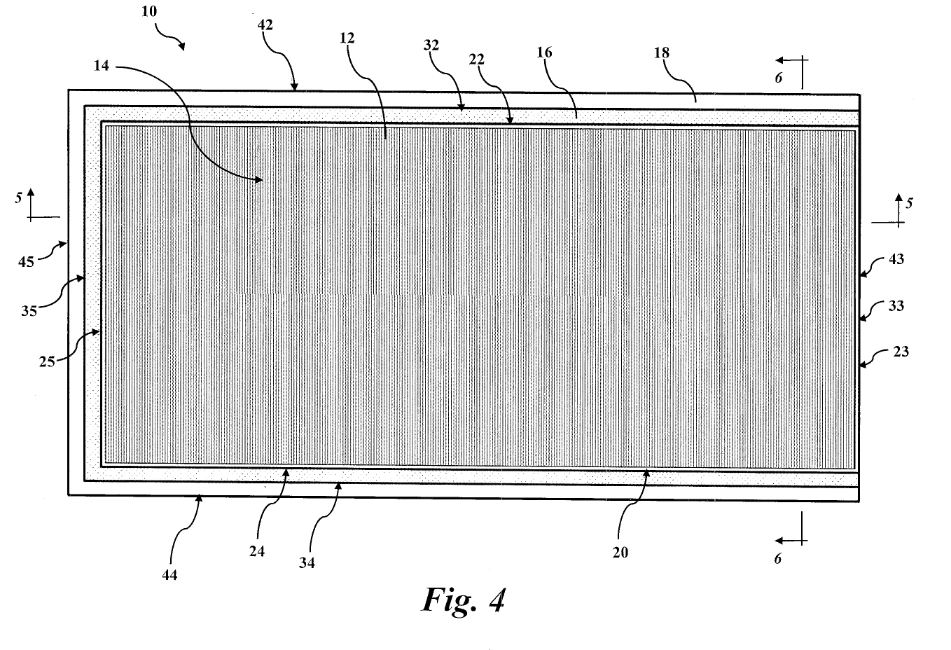

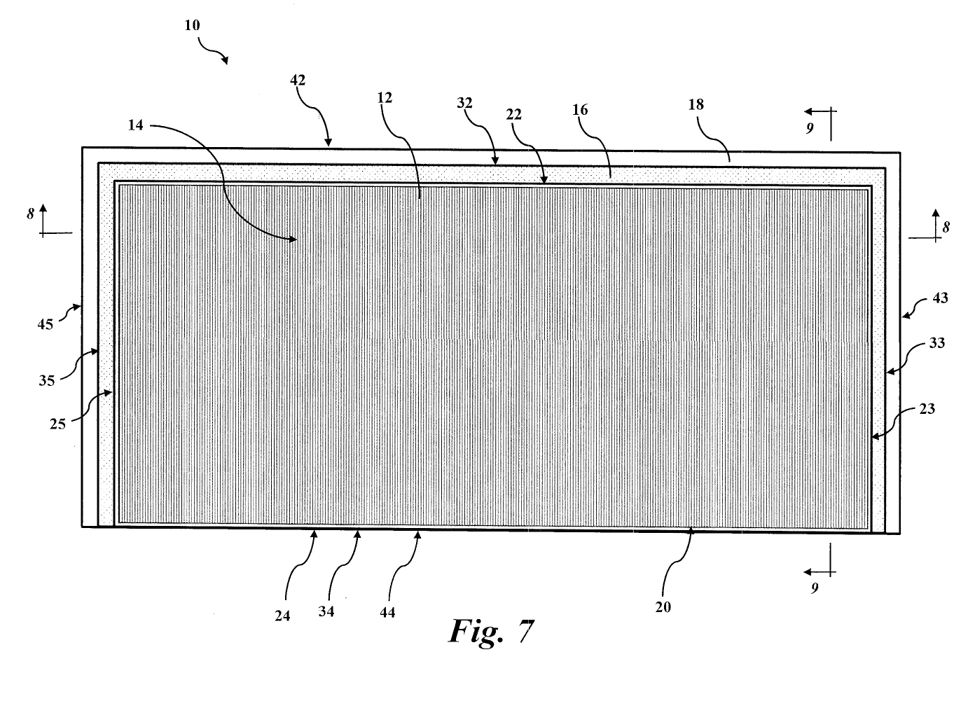

In the embodiments shown in FIGS. 4 and 7 the relative position of the transparent substrate 12 and back panel 18 are shifted off-center such that one or more edges of the back panel 18 extend beyond the transparent substrate 12. These embodiments can be employed when the direction of contact or impact can be predicted, such as when the device 10 is mounted in a fixed position, tilted with respect to the ground, and falling objects are predicted to preferentially contact the top edge of the modules or the edge pointing toward the prevailing winds. Another example is when the solar module travels in known direction on an assembly line or during transportation and installation and it is predicted that objects will preferentially impact the leading edge.

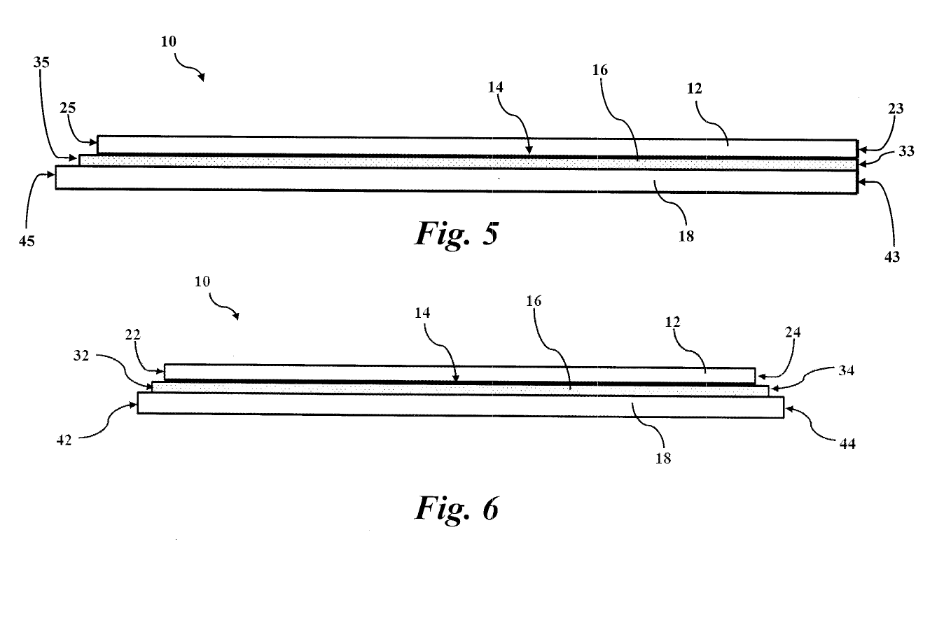

For example, in the exemplary embodiment shown by FIGS. 4-6, the edges 23, 33, 43 of the front substrate 12, the encapsulant layer 16, and the back panel 18, respectively, are substantially aligned with one another. Thus, the back panel 18 does not extend beyond edge 23 of the transparent substrate 12 along its edge 43. However, the other three edges 42, 44, 45 of the back panel 18 extend beyond the respective edges 22, 24, 25 of the transparent substrate 12 and the edges 32, 34, 35 of the encapsulation substrate 16 to define exterior edges of the device 10.

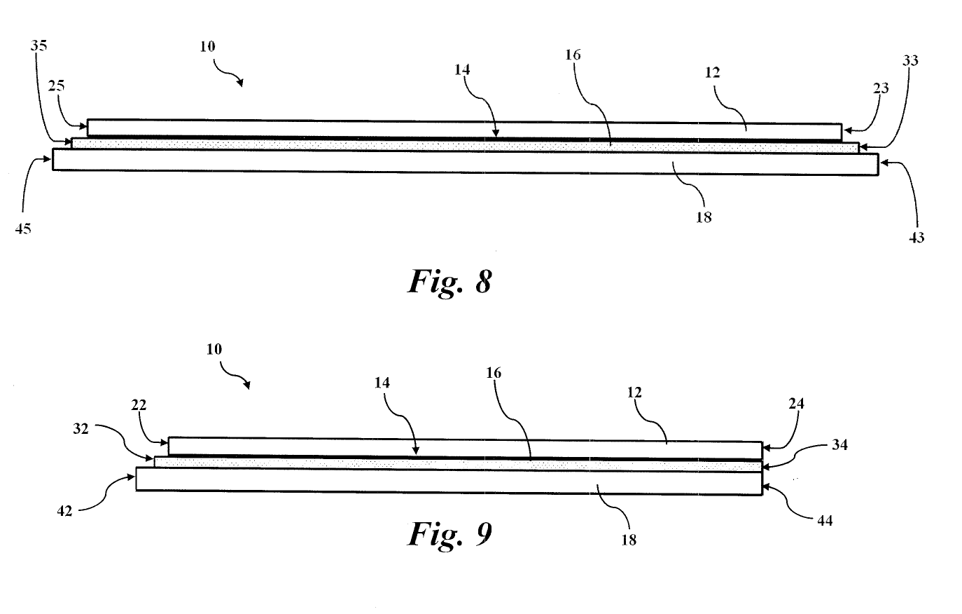

Alternatively, in the exemplary embodiment shown by FIGS. 7-9, the edges 24, 34, 44 of the front substrate 12, the encapsulant layer 16, and the back panel 18, respectively, are substantially aligned with one another. Thus, the back panel 18 does not extend beyond edge 24 of the transparent substrate 12 along its edge 44. However, the other three edges 42, 43, 45 of the back panel 18 extend beyond the respective edges 22, 23, 25 of the transparent substrate 12 and the edges 32, 33, 35 of the encapsulation substrate 16 to define exterior edges of the device 10.

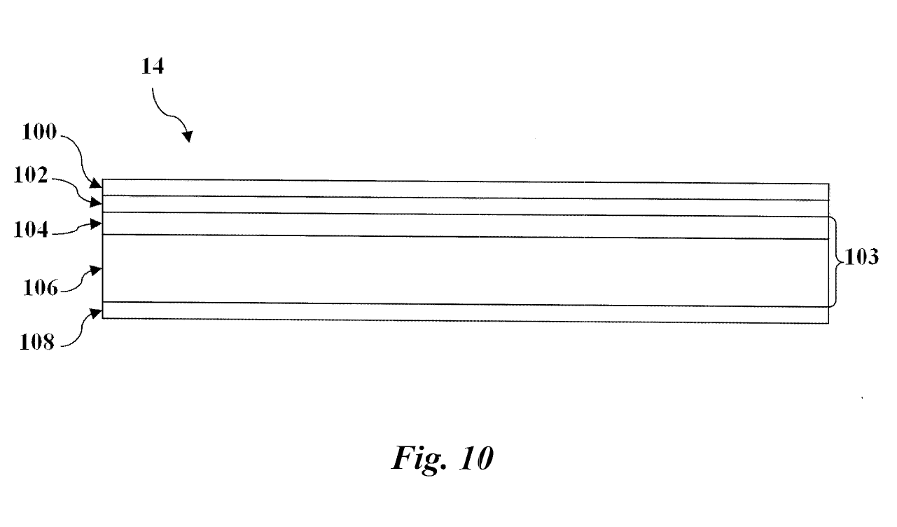

As depicted in FIG. 10, the photovoltaic thin film stack 14 can generally include a transparent conductive oxide layer 100 (a TCO layer), an optional resistive transparent buffer layer 102 (a RTB layer), a photovoltaic heterojunction 103, and back contact layer 108. As shown, the photovoltaic heterojunction 103 is formed from an n-type window layer 104 and an absorber layer 106. In one particular embodiment, the absorber layer 106 can include cadmium telluride (i.e., a cadmium telluride layer). In this embodiment, the n-type window layer 104 can include cadmium sulfide (i.e., a cadmium sulfide layer). Although described as a cadmium telluride thin film stack 14 in the following description of FIG. 10, the oversized back panel 18 can be included in any type of thin film photovoltaic device 10, including superstrate configurations and substrate configurations.

Generally, the TCO layer 100 is positioned on the transparent substrate 12 of the exemplary device 10 in FIGS. 1-9. The TCO layer 100 allows light to pass through with minimal absorption while also allowing electric current produced by the thin film stack 14 to travel sideways to opaque metal conductors (not shown). For instance, the TCO layer 100 can have a sheet resistance less than about 30 ohm per square, such as from about 4 ohm per square to about 20 ohm per square (e.g., from about 8 ohm per square to about 15 ohm per square). The TCO layer 100 can generally include at least one conductive oxide, such as tin oxide, zinc oxide, indium tin oxide, zinc stannate, cadmium stannate, or mixtures thereof. Additionally, the TCO layer 100 can include other conductive, transparent materials. The TCO layer 100 can also include dopants (e.g., fluorine, tin, etc.) and other materials, as desired.

The TCO layer 100 can be formed by sputtering, chemical vapor deposition, spray pyrolysis, or any other suitable deposition method. In one particular embodiment, the TCO layer 100 can be formed by sputtering (e.g., DC sputtering or RF sputtering) on the glass substrate 12. For example, a cadmium stannate layer can be formed by sputtering a hot-pressed target containing stoichiometric amounts of SnO₂ and CdO onto the glass substrate 12 in a ratio of about 1 to about 2. The cadmium stannate can alternatively be prepared by using cadmium acetate and tin (II) chloride precursors by spray pyrolysis. In certain embodiments, the TCO layer 100 can have a thickness between about 0.1 μm and about 1 μm, for example from about 0.1 μm to about 0.5 μm, such as from about 0.25 μm to about 0.35 μm.

An optional resistive transparent buffer layer 102 (RTB layer) is shown on the TCO layer 100 in the thin film stack 14 of FIG. 9. The RTB layer 102 is generally more resistive than the TCO layer 100 and can help protect the thin film stack 14 from chemical interactions between the TCO layer 100 and the subsequent layers and/or the formation of shunts (e.g., extending from the TCO layer 100 to the CdS layer 104). For example, in certain embodiments, the RTB layer 102 can have a sheet resistance that is greater than about 1000 ohms per square, such as from about 10 kOhms per square to about 1000 MOhms per square. The RTB layer 102 can also have a wide optical bandgap (e.g., greater than about 2.5 eV, such as from about 2.7 eV to about 3.5 eV).

Without wishing to be bound by a particular theory, it is believed that the presence of the RTB layer 102 between the TCO layer 100 and the photovoltaic heterjunction 103 can allow for a relatively thin n-type window layer 104 to be included in the thin film stack 14 by reducing the possibility of interface defects (i.e., “pinholes” in the n-type window layer 104) creating shunts between the TCO layer 100 and the absorber layer 106. The RTB layer 102 can include, for instance, a combination of zinc oxide (ZnO) and tin oxide (SnO₂), which can be referred to as a zinc tin oxide layer (“ZTO”). In one particular embodiment, the RTB layer 102 can include more tin oxide than zinc oxide. For example, the RTB layer 102 can have a composition with a stoichiometric ratio of ZnO/SnO₂ between about 0.25 and about 3, such as in about an one to two (1:2) stoichiometric ratio of tin oxide to zinc oxide. The RTB layer 102 can be formed by sputtering, chemical vapor deposition, spray-pyrolysis, or any other suitable deposition method. In one particular embodiment, the RTB layer 102 can be formed by sputtering (e.g., DC sputtering or RF sputtering) on the TCO layer 100. For example, the RTB layer 102 can be deposited using a DC sputtering method by applying a DC current to a metallic source material (e.g., elemental zinc, elemental tin, or a mixture thereof) and sputtering the metallic source material onto the TCO layer 100 in the presence of an oxidizing atmosphere (e.g., O₂ gas). When the oxidizing atmosphere includes oxygen gas (i.e., O₂), the atmosphere can be greater than about 95% pure oxygen, such as greater than about 99%.

In certain embodiments, the RTB layer 102 can have a thickness between about 0.075 μm and about 1 μm, for example from about 0.1 μm to about 0.5 μm. In particular embodiments, the RTB layer 102 can have a thickness between about 0.08 μm and about 0.2 μm, for example from about 0.1 μm to about 0.15 μm.

A cadmium sulfide layer 104 is shown on RTB layer 102 of the exemplary thin film stack 14. The cadmium sulfide layer 104 is a n-type window layer that generally includes cadmium sulfide (CdS) but may also include other materials, such as zinc sulfide, cadmium zinc sulfide, etc., and mixtures thereof as well as dopants and other impurities. In one particular embodiment, the cadmium sulfide layer may include oxygen up to about 25% by atomic percentage, for example from about 5% to about 20% by atomic percentage. The cadmium sulfide layer 104 can have a wide band gap (e.g., from about 2.25 eV to about 2.5 eV, such as about 2.4 eV) in order to allow most radiation energy (e.g., solar radiation) to pass. As such, the cadmium sulfide layer 104 is considered a transparent layer in the thin film stack 14.

The cadmium sulfide layer 104 can be formed by sputtering, chemical vapor deposition, chemical bath deposition, and other suitable deposition methods. In one particular embodiment, the cadmium sulfide layer 104 can be formed by sputtering (e.g., direct current (DC) sputtering or radio frequency (RF) sputtering) on the RTB layer 102. Sputtering deposition generally involves ejecting material from a target, which is the material source, and depositing the ejected material onto the substrate to form the film. DC sputtering generally involves applying a current to a metal target (i.e., the cathode) positioned near the substrate (i.e., the anode) within a sputtering chamber to form a direct-current discharge. The sputtering chamber can have a reactive atmosphere (e.g., an oxygen atmosphere, nitrogen atmosphere, fluorine atmosphere) that forms a plasma field between the metal target and the substrate. The pressure of the reactive atmosphere can be between about 1 mTorr and about 20 mTorr for magnetron sputtering. When metal atoms are released from the target upon application of the voltage, the metal atoms can react with the plasma and deposit onto the surface of the substrate. For example, when the atmosphere contains oxygen, the metal atoms released from the metal target can form a metallic oxide layer on the substrate. The current applied to the source material can vary depending on the size of the source material, size of the sputtering chamber, amount of surface area of substrate, and other variables. In some embodiments, the current applied can be from about 2 amps to about 20 amps. Conversely, RF sputtering generally involves exciting a capacitive discharge by applying an alternating-current (AC) or radio-frequency (RF) signal between the target (e.g., a ceramic source material) and the substrate. The sputtering chamber can have an inert atmosphere (e.g., an argon atmosphere) having a pressure between about 1 mTorr and about 20 mTorr.

Due to the presence of the RTB layer 102, the cadmium sulfide layer 104 can have a thickness that is less than about 0.1 μm, such as between about 10 nm and about 100 nm, such as from about 50 nm to about 80 nm, with a minimal presence of pinholes between the TCO layer 100 and the cadmium sulfide layer 104. Additionally, a cadmium sulfide layer 104 having a thickness less than about 0.1 μm reduces any absorption of radiation energy by the cadmium sulfide layer 104, effectively increasing the amount of radiation energy reaching the underlying cadmium telluride layer 106.

A cadmium telluride layer 106 is shown on the cadmium sulfide layer 104in the exemplary thin film stack 14. The cadmium telluride layer 106 is a p-type layer that generally includes cadmium telluride (CdTe) but may also include other materials. As the p-type layer in the thin film stack 14, the cadmium telluride layer 106 is the photovoltaic layer that interacts with the cadmium sulfide layer 104 (i.e., the n-type layer) to produce current from the adsorption of radiation energy by absorbing the majority of the radiation energy passing into the thin film stack 14 due to its high absorption coefficient and creating electron-hole pairs. For example, the cadmium telluride layer 106 can generally be formed from cadmium telluride and can have a bandgap tailored to absorb radiation energy (e.g., from about 1.4 eV to about 1.5 eV, such as about 1.45 eV) to create the maximum number of electron-hole pairs with the highest electrical potential (voltage) upon absorption of the radiation energy. Electrons may travel from the p-type side (i.e., the cadmium telluride layer 106) across the junction to the n-type side (i.e., the cadmium sulfide layer 104) and, conversely, holes may pass from the n-type side to the p-type side. Thus, the p-n junction formed between the cadmium sulfide layer 104 and the cadmium telluride layer 106 forms a diode in which the charge imbalance leads to the creation of an electric field spanning the photovoltaic heterojunction 103. Conventional current is allowed to flow in only one direction and separates the light induced electron-hole pairs.

The cadmium telluride layer 106 can be formed by any known process, such as vapor transport deposition, chemical vapor deposition (CVD), spray pyrolysis, electro-deposition, sputtering, close-space sublimation (CSS), etc. In one particular embodiment, the cadmium sulfide layer 104 is deposited by sputtering and the cadmium telluride layer 106 is deposited by close-space sublimation. In particular embodiments, the cadmium telluride layer 106 can have a thickness between about 0.1 μm and about 10 μm, such as from about 1 μm and about 5 μm. In one particular embodiment, the cadmium telluride layer 106 can have a thickness between about 1.5 μm and about 4 μm, such as about 2 μm to about 3 μm.

A series of post-forming treatments can be applied to the exposed surface of the cadmium telluride layer 106. These treatments can tailor the functionality of the cadmium telluride layer 106 and prepare its surface for subsequent adhesion to the back contact layer(s) 108. For example, the cadmium telluride layer 106 can be annealed at elevated temperatures (e.g., from about 350° C. to about 500° C., such as from about 375° C. to about 425° C.) for a sufficient time (e.g., from about 1 to about 40 minutes) to create a quality p-type layer of cadmium telluride. Without wishing to be bound by theory, it is believed that annealing the cadmium telluride layer decreases the deep-defect density and makes the CdTe layer more p-type. Additionally, the cadmium telluride layer 106 can recrystallize and undergo grain regrowth during annealing.

Annealing the cadmium telluride layer 106 can be carried out in the presence of cadmium chloride in order to dope the cadmium telluride layer 106 with chloride ions. For example, the cadmium telluride layer 106 can be washed with an aqueous solution containing cadmium chloride then annealed at the elevated temperature (e.g., via heating the photovoltaic heterojunction to a treatment temperature of about 380° C. to about 430° C.).

In one particular embodiment, after annealing the cadmium telluride layer 106 in the presence of cadmium chloride, the surface can be washed to remove any cadmium oxide formed on the surface. This surface preparation can leave a Te-rich surface on the cadmium telluride layer 106 by removing oxides from the surface, such as CdO, CdTeO₃, CdTe₂O₅, etc. For instance, the surface can be washed with a suitable solvent (e.g., ethylenediamine also known as 1,2diaminoethane or “DAE”) to remove any cadmium oxide from the surface.

Additionally, copper can be added to the cadmium telluride layer 106. Along with a suitable etch, the addition of copper to the cadmium telluride layer 106 can form a surface of copper-telluride on the cadmium telluride layer 106 in order to obtain a low-resistance electrical contact between the cadmium telluride layer 106 (i.e., the p-type layer) and the back contact layer(s). Specifically, the addition of copper can create a surface layer of cuprous telluride (Cu₂Te) between the cadmium telluride layer 106 and the back contact layer 108 and/or can create a Cu-doped CdTe layer. Thus, the Te-rich surface of the cadmium telluride layer 106 can enhance the collection of current created by the thin film stack 14 through lower resistivity between the cadmium telluride layer 106 and the back contact layer 108.

Copper can be applied to the exposed surface of the cadmium telluride layer 106 by any process. For example, copper can be sprayed or washed on the surface of the cadmium telluride layer 106 in a solution with a suitable solvent (e.g., methanol, water, or the like, or combinations thereof) followed by annealing. In particular embodiments, the copper may be supplied in the solution in the form of copper chloride, copper iodide, or copper acetate. The annealing temperature is sufficient to allow diffusion of the copper ions into the cadmium telluride layer 106, such as from about 125° C. to about 300° C. (e.g. from about 150° C. to about 250° C.) for about 5 minutes to about 30 minutes, such as from about 10 to about 25 minutes.

A back contact layer 108 is shown on the cadmium telluride layer 106. The back contact layer 108 generally serves as the back electrical contact, in relation to the opposite, TCO layer 100 serving as the front electrical contact. The back contact layer 108 is suitably made from one or more highly conductive materials, such as elemental nickel, chromium, copper, tin, silver, or alloys or mixtures thereof. Additionally, the back contact layer 108 can be a single layer or can be a plurality of layers. In one particular embodiment, the back contact layer 108 can include graphite, such as a layer of carbon deposited on the p-layer followed by one or more layers of metal, such as the metals described above. The back contact layer 108, if made of or comprising one or more metals, is suitably applied by a technique such as sputtering or metal evaporation. If it is made from a graphite and polymer blend, or from a carbon paste, the blend or paste is applied to the semiconductor device by any suitable method for spreading the blend or paste, such as screen printing, spraying or by a “doctor” blade. After the application of the graphite blend or carbon paste, the device can be heated to convert the blend or paste into the conductive back contact layer. A carbon layer, if used, can be from about 0.1 μm to about 10 μm in thickness, for example from about 1 μm to about 5 μm. A metal layer of the back contact, if used for or as part of the back contact layer 108, can be from about 0.1 μm to about 1.5 μm in thickness.

Other thin film layers may also be present in the thin film stack 14. For example, index matching layers can be positioned between the transparent conductive oxide layer 100 and the transparent substrate 14. Additionally, an oxygen getter layer (e.g., comprising alumina) can be positioned between the transparent conductive oxide layer 100 and the resistive transparent buffer layer 102.

Other components (not shown) can be included in the exemplary device 10, such as buss bars, external wiring, laser etches, etc. For example, when the device 10 forms a photovoltaic cell of a photovoltaic module, a plurality of photovoltaic cells can be connected in series in order to achieve a desired voltage, such as through an electrical wiring connection. Each end of the series connected cells can be attached to a suitable conductor such as a wire or bus bar, to direct the photovoltaically generated current to convenient locations for connection to a device or other system using the generated electric. A convenient means for achieving such series connections is to laser scribe the device to divide the device into a series of cells connected by interconnects. In one particular embodiment, for instance, a laser can be used to scribe the deposited layers of the semiconductor device to divide the device into a plurality of series connected cells.

Methods of manufacturing the devices 10 of FIGS. 1-9 are also encompassed by the present disclosure.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. A thin film photovoltaic device, comprising:
a transparent substrate defining a front surface area;
a photovoltaic thin film stack on the transparent substrate; and,
a back panel defining a rear surface area;
wherein the photovoltaic thin film stack is positioned between the transparent substrate and the back panel, and wherein the front surface area is less than the rear surface area.

2. The device of claim 1, further comprising:
an encapsulant layer defining an encapsulant surface area, wherein the encapsulant layer is positioned between the photovoltaic thin film stack and the back panel.

3. The device of claim 2, wherein the encapsulant surface area is greater than the front surface area.

4. The device of claim 3, wherein the encapsulant surface area is less than the rear surface area.

5. The device of claim 1, wherein the back panel extends farther than the transparent substrate along at least one edge of the device.

6. The device of claim 1, wherein the device defines a rectangle having four side edges, and wherein the back panel extends farther than the transparent substrate along at least two edges of the device.

7. The device of claim 6, wherein the back panel extends farther than the transparent substrate along at least three edges of the device.

8. The device of claim 1, wherein the device defines a rectangle having four edges, and wherein the back panel extends farther than the transparent substrate along each edge of the device.

9. The device of claim 1, wherein the front surface area is about 90% to about 99.9% of the rear surface area.

10. The device of claim 9, wherein the front surface area is about 95% to about 99.5% of the rear surface area.

11. The device of claim 9, further comprising:
an encapsulant layer defining an encapsulant surface area, wherein the encapsulant layer is positioned between the photovoltaic thin film stack and the back panel, and wherein the front surface area is about 95% to 100% of the encapsulant surface area.

12. The device of claim 11, wherein the encapsulant surface area is about 95% to 99% of the rear surface area.

13. The device of claim 1, wherein the transparent substrate comprises a glass that has a thickness of about 0.5 mm to about 2.5 mm.

14. The device of claim 1, wherein the photovoltaic thin film stack comprising a transparent conductive oxide layer, a photovoltaic heterojunction, and back contact layer.

15. A thin film photovoltaic device, comprising:
a transparent substrate defining a front surface area;
a photovoltaic thin film stack on the transparent substrate; and,
a back panel defining a rear surface area;
wherein the photovoltaic thin film stack is positioned between the transparent substrate and the back panel, and wherein the back panel extends farther than the transparent substrate along at least one portion of the device.

16. The device of claim 15, wherein the back panel extends farther than the transparent substrate along at least one edge of the device.

17. The device of claim 15, wherein the device defines a rectangle having four side edges, and wherein the back panel extends farther than the transparent substrate along at least two side edges of the device.

18. The device of claim 15, wherein the device defines a rectangle having four side edges, and wherein the back panel extends farther than the transparent substrate along at least three side edges of the device.

19. The device of claim 15, wherein the device defines a rectangle having four side edges, and wherein the back panel extends farther than the transparent substrate along each side edge of the device.

20. A thin film photovoltaic device, comprising:
a transparent substrate defining a front length and a front width;
a photovoltaic thin film stack on the transparent substrate;
an encapsulant layer defining an encapsulant length and an encapsulant width; and,
a back panel defining a rear length and a rear width;
wherein the encapsulant layer is positioned between the photovoltaic thin film stack and the back panel, and wherein at least one of the front length or front width is less than the respective the rear length or rear width.
